(19) United States
(12) Patent Application Publication
(10) Pub. No.: US 2006/0022320 A1
(43) Pub. Date: Feb. 2, 2006

(54) Semiconductor device and manufacturing method thereof

(75) Inventors: Hiroyuki Nakanishi, Soraku-gun (JP); Shinji Suminoe, Tenri-shi (JP)

Correspondence Address: NIXON & VANDERHYE, PC, 901 NORTH GLEBE ROAD, 11TH FLOOR, ARLINGTON, VA, 22203, US

(73) Assignee: SHARP KABUSHIKI KAISHA, Osaka (JP)

(21) Appl. No.: 11/188,785

(22) Filed: Jul. 26, 2005

(30) Foreign Application Priority Data
Jul. 29, 2004 (JP) 2004-222520

(51) Int. Cl. H01R 13/15; H01L 23/02

(52) U.S. Cl. 257/678; 439/259

(57) ABSTRACT

A semiconductor apparatus includes: a first insulating layer formed on an IC chip; a metal wiring having one end connected to a chip electrode pad, and one other end on which an external connection terminal mounting electrode is provided; an electronic component connected to part of the external connection terminal mounting electrode; an external connection terminal, which is made of a conductive material, formed on one other part of the external connection terminal mounting electrode; a second insulating layer covering, at least, (a) part of the external connection terminal mounting electrode to which the electronic component is not mounted, and (b) the metal wiring; and a sealing resin for sealing the electronic component and the external connection terminal in such a manner that the external connection terminal is partially exposed so as to have an exposed portion.

This Nonprovisional application claims priority under 35 U.S.C. § 119(a) on Patent Application No. 2004/222520 filed in Japan on Jul. 29, 2004, the entire contents of which are hereby incorporated by reference.

### FIELD OF THE INVENTION

The present invention relates to a compact semiconductor device having high functionality and reliability, particularly to a wafer-level chip size package (or chip scale package) (CSP). The present invention is an art regarding a configuration of a package in which an integrated circuit (IC) chip is so arranged that another IC chip or an electronic component such as a passive component is mounted on the IC chip.

### BACKGROUND OF THE INVENTION

Recently there is a trend toward high functional portable tools such as a portable phone. Accordingly, for an IC package, which is a component of the portable phone, there has been a growing demand to be compact, light in weight, and highly functional. In order to realize an IC package equivalent in size to an IC chip, a wafer-level CSP has been proposed in which a great number of chips can be packaged on a wafer at once.

As structure of a wafer level CSP100, which is a typical and simple wafer-level CSP, is illustrated in FIGS. 9(a) and 9(b) by way of example. The wafer-level CSP has been proposed and manufactured, and disclosed in a feature article in a magazine. (“Nikkei microdevices” (published by Nikkei BP, published on Aug. 1, 1998, pp. 44 to 59). As illustrated in FIGS. 9(a) and 9(b), the wafer-level CSP includes an IC chip 104, an insulating layers 107, an insulating layer 108, rewired wring 106, and an external connection terminal 101. The insulating layers 107, insulating layer 108, rewired wring 106, and external connection terminal 101 are formed on the IC chip 104.

Further, another structure has been proposed which not only realizes reduction in size without a loss of functionality, but also suppresses deterioration in electronic properties due to long wiring. The another structure is so arranged that an electronic component (such as a passive component or the like) provided in association with an IC chip is mounted an IC package on which the IC chip is mounted. For example, Japanese Laid-Open Patent Publication No. 299496/2002 (Tokukai 2002-299496, publication date: Oct. 11, 2002) discloses a flip chip semiconductor apparatus illustrated in FIG. 10. In this semiconductor apparatus, a passive component 202 is mounted on part of an IC chip electrode 201 of a semiconductor chip 200. In other area on the IC chip electrode 201, a veer 203 is formed. The veer 203 is a metal post substantially equal in height to the passive component 202. On the veer 203, a solder bump 204, which is an external connection terminal, is provided.

In the conventional wafer level CSP100, the external connection terminal 101 must be provided within a size of the IC chip 104. The same is true in a case where the semiconductor chip 200 includes an electronic component such as the passive component 202. Mounting an electronic component on an IC chip allows reduction of the number of external connection terminals which have been required for connecting an external electronic component onto the print circuit board. On the other hand, because this will not allow to place the external connection terminal in an area where the electronic component is to be provided, this will result in increasing the number of the external connection terminals per unit area on an IC chip.

Here, assume a case of employing a solder ball, which is widely used as an external connection terminal. Bonding is carried out by melting the solder ball via heating and then solidifying the solder ball via cooling. Through melting and solidification, the solder ball becomes flattened, thereby expanding in a horizontal direction but decreased in height.

Accordingly, for disposing the external connection terminals densely, solder balls in smaller size are required in order to avoid mutual contact between the external connection terminals. As a result, the height of the external connection terminal is further lower. An electronic component to be mounted on an IC chip has a certain height in order to ensure its performance. Therefore, an IC package with a relatively low height of the external connection terminals would possibly have problems in that when the IC package is mounted on a printed circuit substrate, the component of the IC package touches the printed circuit substrate. In some cases, the relatively low height low height of the external connection terminals would prevent the IC package from being mounted on the printed circuit substrate.

More specifically, since the height of the solder ball will be two-third of its original height due to a weight of a package itself, a distance between top of the solder ball and the printed circuit substrate needs to be at least 1.5 times greater than that of the electronic component. In the case where the solder ball is thus compressed, the solder ball becomes greater in width than in height. Therefore, in order to package a circuit without causing a short circuit between adjacent external connection terminals, a space between one external connection terminal and another external connection terminal is required to be approximately as twice as of the electronic component.

### SUMMARY OF THE INVENTION

An object of the present invention is to provide a semiconductor apparatus and a manufacturing method thereof are provided, each of which realizes a wafer-level CSP on which an electronic component is mounted in such a manner that the electronic component is mounted on re-wiring, wherein the external connection terminal is (i) prevented from being deformed after mounted on the IC chip, from being decreased in height, and from being expanded to a horizontal direction; and (ii) formed with a fine pitch from another external connection terminal located adjacent from the external connection terminal, so that the wafer-level CSP is highly functional and has a large number of pins.

To attain the foregoing object, the semiconductor apparatus of the present invention includes an IC chip; a first insulating layer formed on the IC chip; a metal wiring formed on the first insulating layer, the metal wiring having one end connected to an electrode of the IC chip, and other end on which an external connection terminal mounting electrode is provided; an electronic component connected to part of the external connection terminal mounting electrode; an external connection terminal formed on that part of the external connection terminal mounting electrode to which the electronic component is not connected, the external connection terminal made of a conductive material; a second insulating layer covering, at least, (a) that part of the external connection terminal mounting electrode to which the electronic component is not connected, and (b) the metal wiring; and a resin for sealing at least the electronic component and the external connection terminal in such a manner that the external connection terminal is partially exposed so as to have an exposed portion

Further, to solve the foregoing problem, a manufacturing method of the semiconductor apparatus of the present invention includes steps of: forming a first insulating layer on an IC chip; forming a metal wiring on the first insulating layer, the metal wiring including one end connected to an electrode of the IC chip, and other end on which an external connection terminal mounting electrode is provided; forming a second insulating layer covering, at least, (a) part of the external connection terminal mounting electrode to which an electronic component is not connected, and (b) the metal wiring; forming, on the second insulating layer, an opening for the electronic component and an opening for the external connection terminal, each of the openings exposing therethrough; electrically connecting the electronic component to the exposed external connection terminal mounting electrode through the opening for the electronic component, and forming an external connection terminal made of a conductive material through the opening for the external connection terminal; and sealing, at least, the electronic component and the external connection terminal with a resin in such a manner that the external connection terminal is partially exposed so as to have an exposed portion.

According to the present invention, the first insulating layer is formed on the IC chip. On the first insulating layer, the metal wiring is formed. The metal wiring has one end connected to the electrode of the IC chip, and one other end on which the external connection terminal mounting electrode is provided. Further, on part of the external connection terminal mounting electrode, the electronic component is connected, and on one other part of the external connection terminal mounting electrode, an external connection terminal such as a conductive solder ball is formed. Then, the second insulating layer is formed over the external connection terminal mounting electrode excluding the connecting section with the electronic component, and on the metal wiring. Further, the electronic component and the external connection terminal are sealed so that part of the external connection terminal is exposed. Note that, the second insulating layer and the resin may be formed on an entire part of the IC chip.

As a result, the external connection terminal is prevented from deformation through fusion when the external connection terminal and an electrode of a printed circuit board are bonded with mounting solder material, because the external connection terminal such as a solder ball, for example, is sealed with the resin in such a manner that part of the external connection terminal is exposed. Further, the electronic components will neither contact the printed circuit board nor fall off after the IC chip is mounted on the printed circuit board, because the electronic component is sealed with the resin. In addition, the external connection terminal can be formed with a fine pitch.

Thus, a semiconductor apparatus and a manufacturing method thereof are provided, each of which realizes a wafer-level CSP on which an electronic component is mounted in such a manner that the electronic component is mounted on re-wiring, wherein the external connection terminal is (i) prevented from being deformed after mounted on the IC chip, from being decreased in height, and from being expanded to a horizontal direction; and (ii) formed with a fine pitch from another external connection terminal located adjacent from the external connection terminal, so that the wafer-level CSP is highly functional and has a large number of pins.

For a fuller understanding of the nature and advantages of the invention, reference should be made to the ensuing detailed description taken in conjunction with the accompanying drawings.

### BRIEF DESCRIPTION OF THE DRAWINGS

FIG. 1(a) is a plan view illustrating a wafer level CSP viewed from an external connection terminal side according to one embodiment of a semiconductor apparatus of the present invention, and FIG. 1(b) is a cross-sectional view taken on line A-A of FIG. 1(a).

FIG. 2 is a cross-sectional view illustrating a printed circuit board on which the wafer level CSP is mounted.

FIG. 3 is a cross-sectional view illustrating a wafer level CSP which is formed so that the height of a sealing resin and the height of an external connection terminal are equal to form a continuous single surface.

FIG. 4 is a cross-sectional view illustrating a wafer level CSP in which additional external connection terminal is provided on the external connection terminal.

FIG. 5 is a cross-sectional view illustrating a wafer level CSP in which a portion of an external connection terminal is notched.

FIG. 6 is a cross-sectional view illustrating a wafer level CSP in which a notch is made, the notch notching a portion of an external connection terminal and part of a sealing resin.

FIG. 7 is a cross-sectional view illustrating a wafer level CSP in which an external connection terminal is formed on the notch of the external connection terminal.

FIG. 8 is a cross-sectional view illustrating a wafer level CSP in which a heat resistance resin is injected in a space between electronic components.

FIG. 9(a) is a plan view of a conventional wafer level CSP, and FIG. 9(b) is a cross-sectional view taken on line B-B of FIG. 9(a).

FIG. 10 is a cross-sectional view of another conventional wafer level CSP.

### DESCRIPTION OF THE EMBODIMENTS

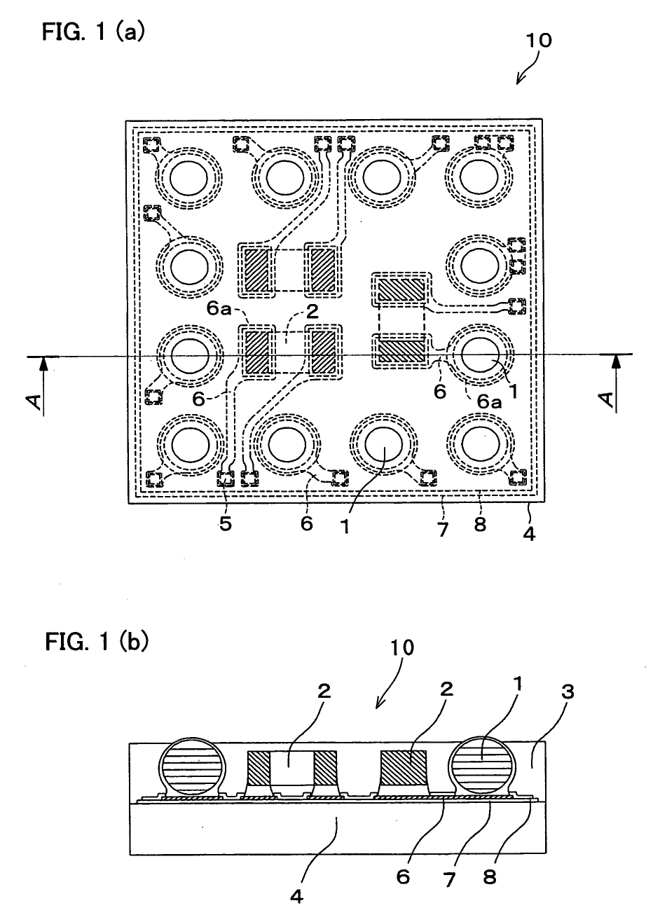

With reference to FIGS. 1 through 8, one embodiment of the present invention is described below. All figures presented in the present embodiment illustrates an IC (Integrated Circuit) package as if it is an IC package that has been diced out from a wafer. It should be previously noted that actual process according to the present invention is carried out when still a plurality of the IC packages are on the wafer (i.e. before dicing). After the process according to the present invention, the wafer is diced into complete IC packages.

As illustrated in FIGS. 1(a) and 1(b), a wafer level CSP (chip size package) 10 of a semiconductor device of the present invention includes a first insulating layer 7, metal wiring 6, a second insulating layer 8, an electronic component 2, an external connection terminal 1, and a chip electrode pad 5 on an IC chip 4. The first insulating layer 7, metal wiring 6, second insulating layer 8, electronic component 2, and external connection terminal 1 are provided in an area where the chip electrode pad 5 is not provided on the IC chip 4. The metal wiring 6 is rewired wiring and is extended from the chip electrode pad 5 to the electronic component 2 or the external connection terminal 1. Further, the insulating layer 8 is formed in an area where the external connection terminal 1 and the electronic component 2 are not mounted. The electronic component 2 may be a passive component such as a chip condenser, chip resistor, or the like, for example.

With reference to FIGS. 1(a) and 1(b), a manufacturing method of the wafer level CSP 10 is described.

First, the insulating layer 7 is formed on the IC chip 4, on which the chip electrode pad 5 is disposed. Then, an opening is made in a region where the chip electrode pad 5 is disposed on the first insulating layer 7. The opening will allow the chip electrode pad 5 to be in contact with the metal wiring 6. The first insulating layer 7 includes an oxide film or nitride film, and an organic film formed on the oxide film or nitride film. The oxide film or nitride film is formed with a CVD method, and has a thickness of approximately 0.5 um. The organic film is made of polymide, Benzocyclobutene (BCB), polybenzooxazole (PBO), or the like. The organic film is formed by photolithography, and has a thickness of approximately 3 to 50 um.

Next, the metal wiring 6 is formed over the first insulating layer 7 by photolithography and electrolytic plating process. Photolithography is performed for making an open pattern on an area where plating is to be applied.

In prior to the plating, a metallic thin film is formed by sputtering. The metallic thin film is a barrier metal/seed layer (i.e., a layer functioning as a barrier metal layer and a seed layer). The metallic thin film is made of Cu/Ti, Cu/Cr, Cu/Tiw, or the like. After the application of plating, chemical etching is performed on an area where the metallic thin film and the metal wiring 6 are not provided.

A layer to which plating is applied on the metal wiring 6 has a thickness of 3 to 5 um for example. The metal wiring 6 is made of Cu, Au/Ni/Cu, or the like.

Further, the second insulating layer 8 is formed on the metal wiring 6 and the first insulating layer 7. On the second insulating layer 8, an openings has to be made so as to expose at least that part of the metal wiring 6 which the external connection terminal 1 and the electronic component 2 are to be mounted. For this, the second insulating layer 8 is made of an organic film made of the organic material(s) mentioned above. The second insulating layer 8, in a thickness of approximately 3 to 50 um, is formed by photolithography in a manner similar to forming the metal wiring 6.

The external connection terminal 1 is made of a metal such as Cu or the like. It is possible to prepare each external connection terminal 1 to be spheres being identical in size and quality by introducing pieces of the metal into inflammation of plasma. Such a technique is disclosed in Japanese Laid-Open Patent Publication No. 71724/2004 (Tokukai 2004-71724, publication date: Mar. 4, 2004), for example. Plating may be applied to a surface of the external connection terminal 1 by using Ni-based solder, SnAg-based solder, or the other type solder.

Mounting of the external connection terminal 1 and the electronic component 2 in the opening may be carried out by melting (fusing) the solder by heart treatment, and solidifying the solder (reflow), the solder previously provided in the opening by printing Sn-, Ag-, or Cu-based solder paste in the opening.

On the other hand, the electronic component 2 may have a function of a capacitor (condenser), inductor (coil), or resistor, for example. FIG. 1(a) and FIG. 1(b) illustrate a capacitor as an example.

Next, the above-mentioned components, which are mounted on the IC chip 4, are coated with a sealing resin 3. That is, with the sealing resin 3, coating is applied to the first insulating layer 7, the second insulating layer 8, the electronic component 2, and the external connection terminal 1. Part of external connection terminal 1 is exposed.

The sealing resin 3, which is formed by mold process or print process, is made of an epoxy-based resin or the like. In the following manner, the sealing resin 3 can be formed so that the external connection terminal 1 is exposed and the electronic component 2 is coated. For example, the external connection terminal 1 is a metal (solder) in a sphere shape with a diameter of 0.4 mm or greater in case of a ceramic capacitor having a size of 0.4×0.2 mm, or a size of 0.6×0.3 mm, and thus having a height of 0.2 to 0.3 mm (standard value).

Further, the sealing resin 3 may be molded in, and the external connection terminal 1 is exposed by providing buffer material inside the mold.

In such a manner, the wafer level CSP is accomplished as illustrated in FIGS. 1(a) and 1(b).

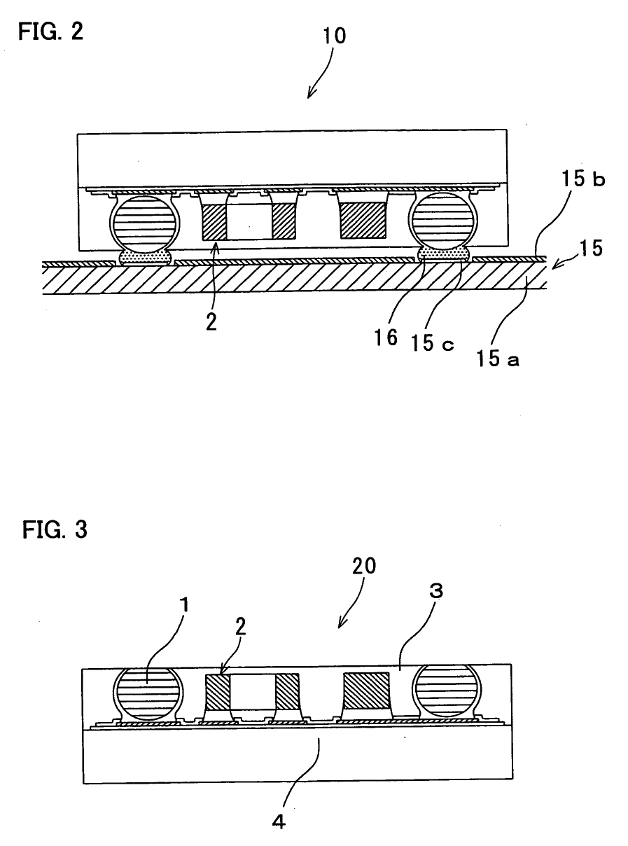

FIG. 2 illustrates a structure in which the wafer level CSP 10 containing the electronic component is mounted on a printed circuit board 15. In the structure, the external connection terminal 1 is disposed to be opposed to the wafer level CSP 10. A bonding pad 15c formed on a base 15a of the printed circuit board 15 is connected with the external connection terminal 1 by using a solder material 16. In other area where the bonding pad 15c is not provided, a solder resist 15b is provided.

The wafer level CSP 10 is mounted on the printed circuit board 15 by reflow soldering, in a manner similar to conventional IC packaging. Even when solder is melted with heat by reflow soldering, the electronic component 2 will not be positionally moved or dropped because the electronic component 2 is sealed inside the sealing resin 3.

In the wafer level CSP 10 containing the electronic component, the exposed portion of the external connection terminal 1 is protruded from the sealing resin 3. However, the present invention is not limited to this arrangement.

For example, the present invention may have a structure of a wafer-level CSP 20 illustrated in FIG. 3. In the structure, the exposed portion of the external connection terminal 1 is not protruded from the sealing resin 3, the exposed portion and the sealing resin 3 has a same level (flat). Thus, the wafer-level CSP 20 is of component-contained type.

The wafer level CSP 20 can be obtained by removing the protruded portion of the external connection terminal 1 cross-sectionally illustrated in FIG. 1(b). However, the present invention is not limited to this. The wafer level CSP 20 may be accomplished by (i) forming the sealing resin 3 so that not only the electronic component 2 but also the external connection terminal 1 is completely under a top surface of the sealing resin 3, and (ii) polishing the top surfaces of the sealing resin 3 and the external connection terminal 1. In this case, the sealing resin 3 may be formed by print process in lieu of mold process.

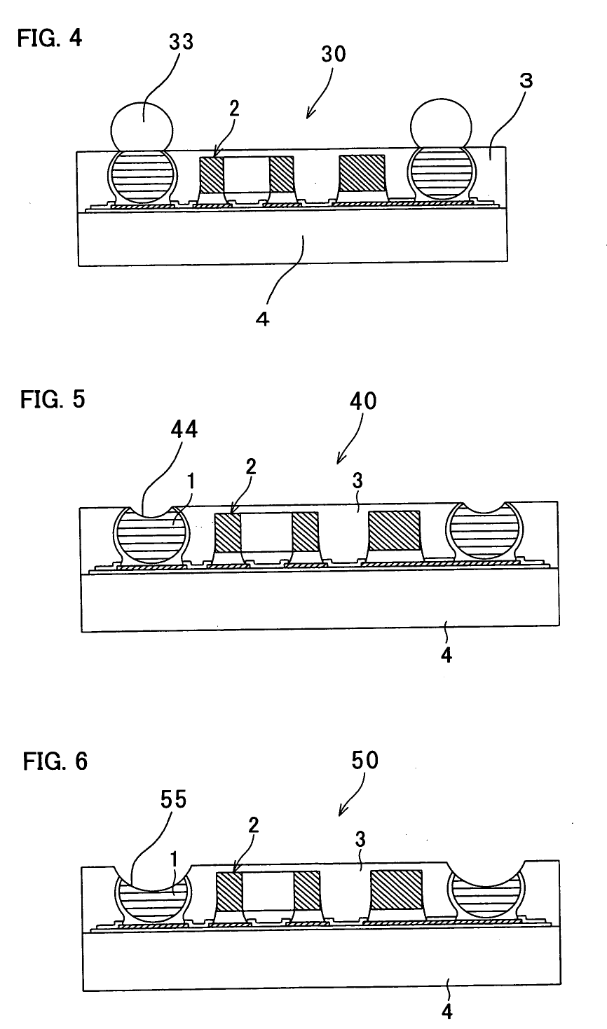

Further, the present embodiment may be arranged as illustrated in FIG. 4. In FIG. 4, a wafer level CSP 30 of the present embodiment is illustrated. In the wafer level CSP 30, an external connection terminal 33 may be attached to the exposed portion of the external connection terminal 1 illustrated in FIG. 3. A printed circuit board 15 is isolated from the IC chip 4 by thicknessess of the external connection terminal 33 and the IC chip 4, thereby achieving high reliability in packaging of the wafer level CSP 30.

In general, there is a large difference between the IC chip 4 and the printed circuit substrate 15 in terms of thermal expansion coefficients. For example, the thermal expansion coefficient of the IC chip 4 is approximately 3×10⁻⁶ degrees Celsius, and the thermal expansion coefficient of the mounting board is approximately 15×10⁻⁶ degrees Celsius. Therefore, temperature change causes stress between the IC chip 4 and the printed circuit substrate 15 in a horizontal direction. That is, as a result of the temperature change, a force is applied on the external connection terminal 33 sandwiched between the sections expanding/shrinking at different rates, the force trying to deform the external connection terminal 33. Therefore, increasing a thickness of the sealing resin 3 and thereby securing a distance between the IC chip 4 and the printed circuit substrate 15 provides stress relaxation in the horizontal direction.

Further, part of exposed portion of the external connection terminal 1 illustrated in FIG. 3 may be removed, as illustrated in a wafer level CSP 40 and a wafer level CSP 50 illustrated in FIG. 5 and in FIG. 6, respectively.

In the wafer level CSP 40 and the wafer level CSP 50, a method for removing part of the external connection terminal 1 may be carried out, for example, by using a machine, especially a drill.

For example, the external connection terminal 1 may be processed partially. As illustrated in FIG. 5, only the exposed portion of the external connection terminal 1 may be processed to make a notch 44 therein as a receiving section. Further, as shown in FIG. 6, part of the sealing resin 3 may be also processed together with the exposed portion of the external connection terminal 1 to make a notch 55 as a receiving section.

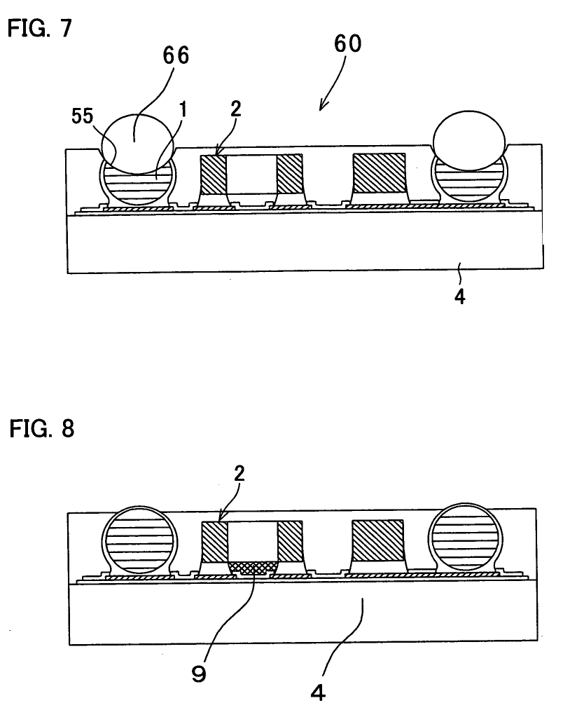

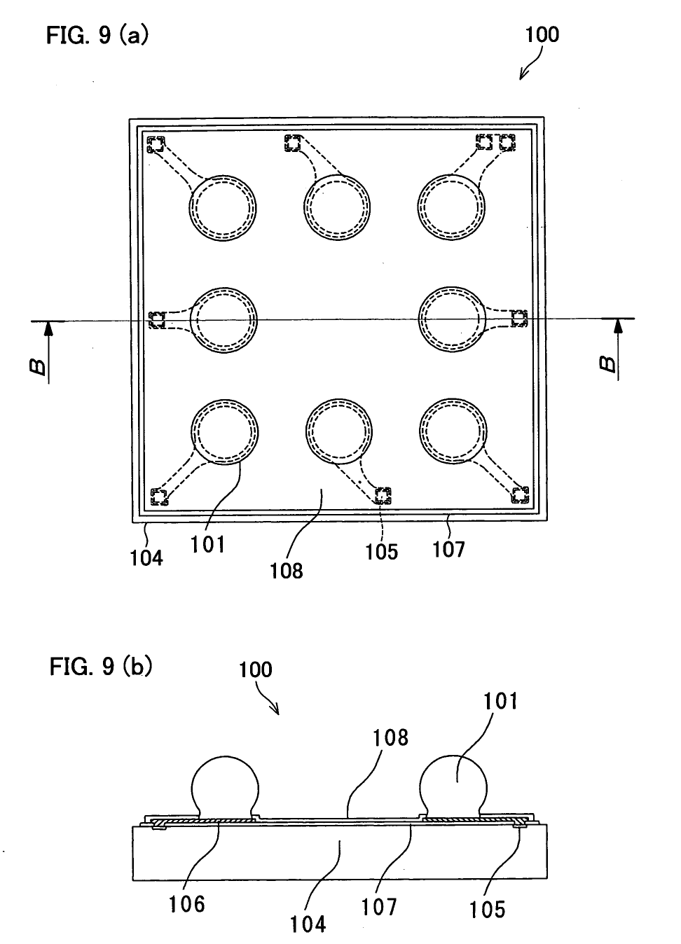

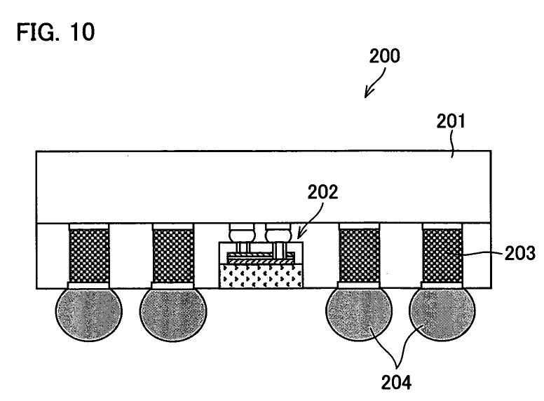

Further, the present embodiment may be arranged as illustrated in FIG. 7. FIG. 7 illustrates a wafer level CSP 60 in which a connection terminal 66 is attached to the processed portion of the external connection terminal 1 illustrated in FIG. 6. An external connection terminal 66 may be attached to the notch 44, which are the processed portion of the external connection terminal 1 shown in FIG. 5 (no drawing of this arrangement is not provided here). Compared to the structure shown in FIG. 4, these structures having the notch provide a larger contact area for attaching the external connection terminal 66 thereto, thereby achieving high reliability in mounting and suppressing an overall thickness of the IC package.

The external connection terminals 66 may be formed by reflow process, for example, after a SnAgCu solder ball is bonded to the receiving section, or after SnAgCu solder paste is printed.

On the other hand, a heat resistance resin 9 may be provided between the IC chip 4 and the electronic component 2 as illustrated in FIG. 8. The heat resistance resin 9 causes the electronic component 2 to be held on the IC chip 4. The heat resistance resin 9, which is an underfilling material, is injected by means of a dispenser and a nozzle. The heat resistance resin 9 is thermally curable. The heat resistance resin 9 is provided in order to prevent water from being reserved in an unsealed space and remained between the IC chip 4 and the electronic component 2 after formation of the sealing resin 3, thereby preventing in advance damage of the IC package due to volumetric increase of water caused by heat in mounting the IC chip 4 on the substrate. The present invention is not limited to the structure illustrated in FIG. 8, in which the heat resistance 9 is added to the structure shown in FIG. 1(b). For example, the heat resistance 9 may be provided to any of the wafer-level CSPs 10 through 60 illustrated in FIGS. 3 through 7, respectively. Further, the present invention is not limited to the structure illustrated in FIG. 8, in which the heat resistance resin 9 is provided only between the IC chip 4 and the electronic component 2. The heat resistance resin 9 may be provided filled in a peripheral area, encapsulating a solder bonding section.

According to the present embodiment, in the wafer level CSP on which the electronic component 2 is mounted in such a matter that the electronic component 2 is mounted on re-wring such as the metal wiring 6, the external connection terminal 1 is a metallic sphere mainly made of copper, nickel, or aluminum, which is hard to be compressed. With this, the external connection terminal 1 is prevented from being deformed after mounted on the IC chip 4. Accordingly, the external connection terminal 1 is prevented from being decreased in height, and from being expanded to the horizontal direction. This realizes such a wafer-level CSP that achieves high functionality with many pins by forming balls (i.e. external connection terminals 1) densely with fine pitches. Further, according to the present embodiment, the electronic component 2 is sealed in (i.e. encapsulated) with the sealing resin resin 3, but the external connection terminal 1 is exposed from the sealing resin 3. This realizes a highly reliable IC package because the electronic component 2 is sealed with the sealing resin 3, which prevents the electronic component 2 from falling off. In addition, mounting the metallic sphere may be carried out by using a conventional apparatus for mounting solder balls.

As described above, in the wafer level CPS 10, 20, 30, 40, 50, and 60 of the present embodiment, the first insulating layer 7 is formed on the IC chip 4. On the first insulating layer 7, the metal wiring 6 is provided. One end of the metal wiring 6 is bonded to the chip electrode pad 5 on the IC chip 4. On the other end of the metal wiring 6, an external connection terminal mounting electrode 6a is formed. Further, part of the external connection terminal mounting electrode 6a is connected to the electronic component 2, while one other part of the external connection terminal mounting electrode 6a is connected to the external connection terminal 1. The external connection terminal 1 is made of a conductive material such as a solder ball or the like, for example. Then, the second insulating layer 8 is formed on that part of the external connection terminal mounting electrode 6a to which the electronic component 2 is not connected. The second insulating layer 8 is also formed on the metal wiring 6. Further, the electronic component 2 and the external connection terminal 1 are sealed with the sealing resin 3 in such a manner that part of the external connection terminal 1 is exposed. Here, the second insulating layer 8 and the sealing resin 3 may seal the entire IC chip 4.

As a result, because the external connection terminal 1 such as a solder ball is sealed with the sealing resin 3 in such a manner that part of the external connection terminal 1 is exposed, the external connection terminal 1 is prevented from being deformed through fusion in connecting the external connection terminal 1 with the bonding pad 15c of the printed circuit board 15 by using the solder material 16. In addition, after the IC chip 4 is mounted on the printed circuit board 15, the electronic component 2 is prevented from contacting with the printed circuit board 15 and from falling off, because the electronic component 2 is sealed with the sealing resin 3. Further, the external connection terminals can be formed with fine pitches.

Thus, a semiconductor apparatus and a manufacturing method thereof are provided, each of which realizes a wafer-level CSP (CSP 10) on which an electronic component 2 (other electronic component than the CSP) is mounted in such a manner that the electronic component 2 is mounted on re-wiring, wherein the external connection terminal 1 is (i) prevented from being deformed after mounted on the IC chip 4, from being decreased in height, and from being expanded to a horizontal direction; and (ii) formed with a fine pitch from another external connection terminal 1 located adjacent from the external connection terminal 1 (i.e. the external connection terminals 1 are formed with fine pitches), so that the wafer-level CSP (CSP 10) is highly functional and has a large number of pins.

Further, in the wafer level CSP 10 of the present embodiment, a solder ball may be used for the external connection terminals 1 because the external connection terminals 1 is designed to be in a sphere shape.

Further, in the wafer level CSP 20 of the present embodiment, the exposed portion of the external connection terminal 1 is in a round shape by removing part of the spherical conductive material. A surface of the round portion (exposed portion) is continuous with a surface of the sealing resin 3 (i.e. forms a single continuous surface with the sealing resin 3). Thus, the wafer level CSP 20 is similar to a widely known land grid array (LGA) from outward appearance, and satisfies a need for a thinner package (in other words, the arrangement of the CSP 20 is effective in case where it is necessary to have a thinner package).

Further, in the wafer level CSP 10, 20, 30, 40, 50, or 60 of the present embodiment, deformation of the external connection terminal 1 is extremely small even when fusion occurs, because the conductive material is mainly made of copper, aluminum, or nickel.

Further, in the wafer level CSP 30 or 60 of the present embodiment, the external connection terminal 33 or 66, which is a conductive protrusion, is formed on the exposed portion of the external connection terminal 1. By fusing the external connection terminal 33 or 66, the bonding pad 15c of the printed circuit board 15, and the external connection terminal 1 can be bonded to each other without using the packaging solder material 16.

Further, in the wafer level CSP 40, 50, or 60 of the present embodiment, the external connection terminal 1 is notched so that part of or the entire part of the exposed portion of the external connection terminal 1 serves as notches 44 or 55. This provides a larger contact area, thereby achieving high reliability in packaging (i.e. mounting). In addition, a protrusion such as the external connection terminal 33 or 66, or the like, can be provided easily on the notches 44 or 55, respectively.

Further, in the wafer level CSP 60 of the present embodiment, the external connection terminal 66, which is a conductive protrusion, is formed on the notches 44 and 55. Thus, the conductive external connection terminal 66 can be used as bonding material for bonding the external connection terminal or the like.

Further, in the wafer level CSP 60 of the present embodiment, packaging can be accomplished in a manner similar to IC packaging of a widely known BGA, in which a solder ball is used for the external connection terminal, because the conductive external connection terminal 66 is mainly made of tin alloy.

Further, in the wafer level CSP 10, 20, 30, 40, 50, or 60, the electronic component 2 may be at least a capacitor, inductor, or resistor.

Further, in the wafer level CSP 10, 20, 30, 40, 50, or 60, the electronic component 2 may be interconnected to part of the metal wiring 6, not to part of the external connection terminal mounting electrode 6a. This provides more flexibility in mounting the electronic component 2.

Further, in the wafer level CSP 10, 20, 30, 40, 50, or 60, the heat resistance resin 9 is provided between (a) the electronic component 2 and (b) the first insulating layer 7 on the IC chip 4. The heat resistance resin 9 causes the electronic component 2 to be held on the IC chip 4.

Thus, this arrangement prevents water from being reserved in an unsealed space and remained between the IC chip 4 and the electronic component 2 after formation of the sealing resin 3, thereby preventing in advance damage of the IC package due to volumetric increase of water caused by heat in mounting the IC chip 4 on the substrate.

As described above, in an IC package containing a wafer level CSP, solder is widely used as an external connection terminal. However, an external connection terminal is decreased in height through fusion of the solder by reflow soldering. Accordingly, when an electronic component is mounted to a wafer level CSP having a simple structure, a solder ball and an electronic component will be equal in height due to the fusion of solder. This may result in failure in bonding a solder ball to a printed circuit board.

According to the arrangement of the present invention, a highly reliable and functional IC package containing an electronic component is realized with a simple manufacturing method. By employing a metallic sphere, which is hard to be fused by reflow soldering, as an external connection terminal or as part of external connection terminal, an existing ball packaging apparatus is still available for instantly arranging a metallic sphere. Unlike the conventional method, this realizes cost-effective manufacture, which will not require costly metal-post plating.

Further, in the semiconductor apparatus of the present invention, the external connection terminal has a sphere shape.

Thus, solder balls can be used as external connection terminals.

Further, in the semiconductor apparatus of the present invention, the exposed portion of the external connection terminal has a round surface by removing a portion of a spherical shape of the conductive material, the round surface being continuous with a surface of the resin.

Thus, the wafer level CSP is similar to a widely known land grid array (LGA) from outward appearance, and satisfies a need for a thinner package.

Further, in the semiconductor apparatus of the present invention, the conductive material mainly contains copper, aluminum, or nickel.

Thus, deformation is extremely small even when fusion occurs.

Further, in the semiconductor apparatus of the present invention, a conductive protrusion is formed on the exposed portion of the external connection terminal.

Thus, by melting the conductive protrusion, the electrode of the printed circuit board and the external connection terminal can be bonded to each other without using the mounting solder material.

Further, in the semiconductor apparatus of the present invention, part of or an entire part of the exposed portion of the external connection terminal is removed so that the external connection terminal has a receiving section.

Thus, higher reliability is achieved due to the enlarged bonding area, by using part of or the entire part of the exposed portion of the external connection terminal as the receiving section. In addition, a protrusion such as an external connection terminal can be easily provided.

Further, in the semiconductor apparatus of the present invention, a conductive protrusion is formed on the receiving section of the external connection terminal.

Thus, the conductive protrusion can be used as bonding material such as the external connection terminal.

Further, in the semiconductor apparatus of the present invention, the conductive protrusion is made of metal alloy which mainly contains tin.

Thus, a solder ball can be used for packaging an IC package, which is equivalent to an IC package of widely known BGA.

Further, in the semiconductor apparatus of the present invention, the electronic component has a function of at least any one of a capacitor, inductor, and resistor.

Thus, at least a capacitor, inductor, or resistor can be used as the electronic component.

Further, in the semiconductor apparatus of the present invention, the electronic component is interconnected to part of the metal wiring, in lieu of being connected with part of the external connection terminal mounting electrode.

Thus, the electronic component can be mounted more flexibly.

Further, in the semiconductor apparatus of the present invention, a heat resistance resin is provided between (a) the electronic component and (b) the first insulating layer on the IC chip, the heat resistance resin causing the electronic component to be held on the IC chip.

This prevents water from being reserved in an unsealed space and remained between the IC chip and the electronic component after formation of the sealing resin.

The invention being thus described, it will be obvious that the same way may be varied in many ways. Such variations are not to be regarded as a departure from the spirit and scope of the invention, and all such modifications as would be obvious to one skilled in the art are intended to be included within the scope of the following claims.

What is claimed is:

1. A semiconductor apparatus comprising:
an IC chip;
a first insulating layer formed on the IC chip;
a metal wiring formed on the first insulating layer, the metal wiring having one end connected to an electrode of the IC chip, and other end on which an external connection terminal mounting electrode is provided;
an electronic component connected to part of the external connection terminal mounting electrode;
an external connection terminal formed on that part of the external connection terminal mounting electrode to which the electronic component is not connected, the external connection terminal made of a conductive material;
a second insulating layer covering, at least, (a) that part of the external connection terminal mounting electrode to which the electronic component is not connected, and (b) the metal wiring; and
a resin for sealing at least the electronic component and the external connection terminal in such a manner that the external connection terminal is partially exposed so as to have an exposed portion.

2. The semiconductor apparatus according to claim 1, wherein the external connection terminal has a sphere shape.

3. The semiconductor apparatus according to claim 1, wherein the exposed portion of the external connection terminal has a round surface by removing a portion of a spherical shape of the conductive material, the round surface being continuous with a surface of the resin.

4. The semiconductor apparatus according to claim 1, wherein the conductive material mainly contains copper, aluminum, or nickel.

5. The semiconductor apparatus according to claim 2, wherein the conductive material mainly contains copper, aluminum, or nickel.

6. The semiconductor apparatus according to claim 3, wherein the conductive material mainly contains copper, aluminum, or nickel.

7. The semiconductor apparatus according to claim 1, wherein a conductive protrusion is formed on the exposed portion of the external connection terminal.

8. The semiconductor apparatus according to claim 2, wherein a conductive protrusion is formed on the exposed portion of the external connection terminal.

9. The semiconductor apparatus according to claim 3, wherein a conductive protrusion is formed on the exposed portion of the external connection terminal.

10. The semiconductor apparatus according to claim 1, wherein part of or an entire part of the exposed portion of the external connection terminal is removed so that the external connection terminal has a receiving section.

11. The semiconductor apparatus according to claim 2, wherein part of or an entire part of the exposed portion of the external connection terminal is removed so that the external connection terminal has a receiving section.

12. The semiconductor apparatus according to claim 3, wherein part of or an entire part of the exposed portion of the external connection terminal is removed so that the external connection terminal has a receiving section.

13. The semiconductor apparatus according to claim 10, wherein a conductive protrusion is formed on the receiving section of the external connection terminal.

14. The semiconductor apparatus according to claim 11, wherein a conductive protrusion is formed on the receiving section of the external connection terminal.

15. The semiconductor apparatus according to claim 12, wherein a conductive protrusion is formed on the receiving section of the external connection terminal.

16. The semiconductor apparatus according to claim 13, wherein the conductive protrusion is made of metal alloy which mainly contains tin.

17. The semiconductor apparatus according to claim 14, wherein the conductive protrusion is made of metal alloy which mainly contains tin.

18. The semiconductor apparatus according to claim 15, wherein the conductive protrusion is made of metal alloy which mainly contains tin.

19. The semiconductor apparatus according to claim 1, wherein the electronic component has a function of at least any one of a capacitor, inductor, and resistor.

20. The semiconductor apparatus according to claim 2, wherein the electronic component has a function of at least any one of a capacitor, inductor, and resistor.

21. The semiconductor apparatus according to claim 3, wherein the electronic component has a function of at least any one of a capacitor, inductor, and resistor.

22. The semiconductor apparatus according to claim 1, wherein the electronic component is interconnected to part of the metal wiring, in lieu of being connected with part of the external connection terminal mounting electrode.

23. The semiconductor apparatus according to claim 1, wherein a heat resistance resin is provided between (a) the electronic component and (b) the first insulating layer on the IC chip, the heat resistance resin causing the electronic component to be held on the IC chip.

24. The semiconductor apparatus according to claim 2, wherein a heat resistance resin is provided between (a) the electronic component and (b) the first insulating layer on the IC chip, the heat resistance resin causing the electronic component to be held on the IC chip.

25. The semiconductor apparatus according to claim 3, wherein a heat resistance resin is provided between (a) the electronic component and (b) the first insulating layer on the IC chip, the heat resistance resin causing the electronic component to be held on the IC chip.

26. A manufacturing method of a semiconductor apparatus comprising steps of:
forming a first insulating layer on an IC chip;
forming a metal wiring on the first insulating layer, the metal wiring including one end connected to an electrode of the IC chip, and other end on which an external connection terminal mounting electrode is provided;
forming a second insulating layer covering, at least,
(a) part of the external connection terminal mounting electrode to which an electronic component is not connected, and (b) the metal wiring;
forming, on the second insulating layer, an opening for the electronic component and an opening for the external connection terminal, each of the openings exposing therethrough;
electrically connecting the electronic component to the exposed external connection terminal mounting electrode through the opening for the electronic component, and forming an external connection terminal made of a conductive material through the opening for the external connection terminal; and
sealing, at least, the electronic component and the external connection terminal with a resin in such a manner that the external connection terminal is partially exposed so as to have an exposed portion.
